(19) United States
(12) Patent Application Publication
(10) Pub. No.: US 2024/0023250 A1
(43) Pub. Date: Jan. 18, 2024

(54) WIRING SUBSTRATE

(71) Applicant: IBIDEN CO., LTD., Ogaki (JP)

(72) Inventors: Toshiki FURUTANI, Ibi-gun (JP); Masashi KUWABARA, Ibi-gun (JP)

(73) Assignee: IBIDEN CO., LTD., Ogaki (JP)

(21) Appl. No.: 18/350,778

(22) Filed: Jul. 12, 2023

(30) Foreign Application Priority Data
Jul. 14, 2022 (JP) 2022-113329

(51) Int. Cl. H05K 3/46; H05K 1/11

(52) U.S. Cl. CPC H05K 3/4655; H05K 1/115; H05K 3/4661; H05K 2201/096; H05K 2201/0209

(57) ABSTRACT

A wiring substrate includes a core substrate; a first build-up part including first conductor layers, a second build-up part including second conductor layers, a third build-up part including third conductor layers and having the outermost surface of the wiring substrate, and a fourth build-up part including one or more fourth conductor layers and having the outermost surface of the wiring substrate. The minimum wiring width of wirings in the third conductor layers is smaller than that of wirings in the first, second and fourth conductor layers. The minimum inter-wiring distance of the wirings in the third conductor layers is smaller than that of the wirings in the first, second and fourth conductor layers. The wirings in the third conductor layers have the minimum wiring width of 3 μm or less, the minimum inter-wiring distance of 3 μm or less, and an aspect ratio in the range of 2.0 to 4.0.

### CROSS-REFERENCE TO RELATED APPLICATIONS

The present application is based upon and claims the benefit of priority to Japanese Patent Application No. 2022-113329, filed Jul. 14, 2022, the entire contents of which are incorporated herein by reference.

### BACKGROUND OF THE INVENTION

### Field of the Invention

The present invention relates to a wiring substrate.

### Description of Background Art

Japanese Patent Application Laid-Open Publication No. 2019-75398 describes a printed wiring board including a core substrates, a first low-density build-up layer formed on a first surface of the core substrate, a second low-density build-up layer formed on a second surface of the core substrate, a first high-density build-up layer formed on the first low-density build-up layer on the opposite side with respect to the core substrate, and a second high-density build-up layer formed on the second low-density build-up layer on the opposite side with respect to the core substrate. The entire contents of this publication are incorporated herein by reference.

### SUMMARY OF THE INVENTION

According to one aspect of the present invention, a wiring substrate includes a core substrate; a first build-up part formed on a first surface of the core substrate and including first insulating layers and first conductor layers, a second build-up part formed on a second surface of the core substrate on the opposite side with respect to the first surface and including second insulating layers and second conductor layers, a third build-up part formed on the first build-up part and including third insulating layers and third conductor layers such that the third build-up part has the outermost surface forming the outermost surface of the wiring substrate, and a fourth build-up part formed on the second build-up part and including one or more fourth insulating layers and one or more fourth conductor layers such that the fourth build-up part has the outermost surface forming the outermost surface of the wiring substrate. The third build-up part is formed such that the minimum wiring width of wirings in the third conductor layers is smaller than the minimum wiring width of wirings in the first conductor layers, the second conductor layers, and the fourth conductor layer, the minimum inter-wiring distance of the wirings in the third conductor layers is smaller than the minimum inter-wiring distance of the wirings in the first conductor layers, the second conductor layers, and the fourth conductor layer, and the wirings in the third conductor layers have the minimum wiring width of 3 μm or less, the minimum inter-wiring distance of 3 μm or less, and an aspect ratio in the range of 2.0 to 4.0.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view illustrating an example of a wiring substrate according to an embodiment of the present invention;

FIG. 2 is a partial enlarged view of FIG. 1, which illustrates an example of the wiring substrate according to the embodiment of the present invention;

FIG. 3 is a partially enlarged view of another example of a wiring substrate according to an embodiment of the present invention;

FIG. 4A is a cross-sectional view illustrating a method for manufacturing a wiring substrate according to an embodiment of the present invention;

FIG. 4B is a cross-sectional view illustrating a method for manufacturing a wiring substrate according to an embodiment of the present invention;

FIG. 4C is a cross-sectional view illustrating a method for manufacturing a wiring substrate according to an embodiment of the present invention;

FIG. 4D is a cross-sectional view illustrating a method for manufacturing a wiring substrate according to an embodiment of the present invention;

FIG. 4E is a cross-sectional view illustrating a method for manufacturing a wiring substrate according to an embodiment of the present invention;

FIG. 4F is a cross-sectional view illustrating a method for manufacturing a wiring substrate according to an embodiment of the present invention;

FIG. 4G is a cross-sectional view illustrating a method for manufacturing a wiring substrate according to an embodiment of the present invention;

FIG. 4H is a cross-sectional view illustrating a method for manufacturing a wiring substrate according to an embodiment of the present invention;

FIG. 4I is a cross-sectional view illustrating a method for manufacturing a wiring substrate according to an embodiment of the present invention;

FIG. 4J is a cross-sectional view illustrating a method for manufacturing a wiring substrate according to an embodiment of the present invention;

FIG. 4K is a cross-sectional view illustrating a method for manufacturing a wiring substrate according to an embodiment of the present invention;

FIG. 4L is a cross-sectional view illustrating a method for manufacturing a wiring substrate according to an embodiment of the present invention; and

FIG. 4M is a cross-sectional view illustrating a method for manufacturing a wiring substrate according to an embodiment of the present invention.

### DETAILED DESCRIPTION OF THE EMBODIMENTS

Embodiments will now be described with reference to the accompanying drawings, wherein like reference numerals designate corresponding or identical elements throughout the various drawings.

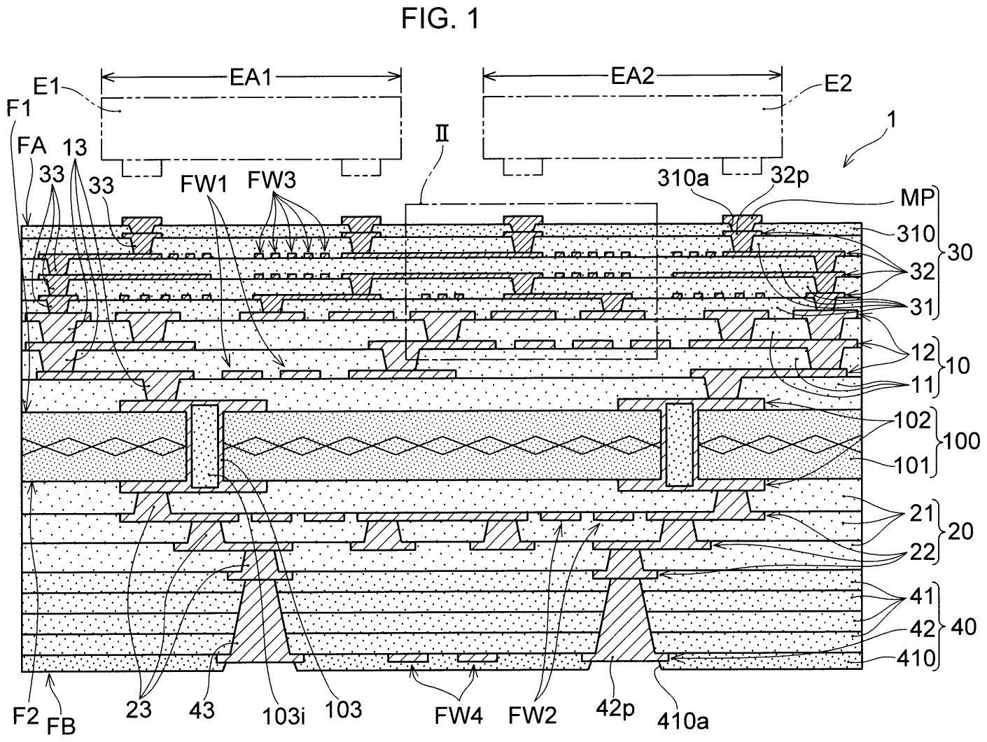

A wiring substrate according to an embodiment of the present invention is described with reference to the drawings. FIG. 1 illustrates a cross-sectional view of a wiring substrate 1 as an example structure according to an embodiment of the present invention.

As illustrated in FIG. 1, the wiring substrate 1 includes a core substrate 100 that includes an insulating layer (core insulating layer) 101 and conductor layers (core conductor layers) 102 that are respectively formed on both sides of the core insulating layer 101. On each of both sides of the core substrate 100, insulating layers and conductor layers are alternately laminated. In the illustrated example, on a first surface (F1) of the core substrate 100, a first build-up part 10 is formed in which multiple insulating layers 11 and multiple conductor layers 12 are alternately laminated. Further, on a second surface (F2) of the core substrate 100, a second build-up part 20 is formed in which multiple insulating layers 21 and multiple conductor layers 22 are alternately laminated.

On an upper side of the first build-up part 10 (opposite side with respect to the core substrate 100), a third build-up part 30 is formed in which multiple insulating layers 31 and multiple conductor layers 32 are alternately laminated. On an upper side of the second build-up part 20 (opposite side with respect to the core substrate 100), a fourth build-up part 40 is formed in which insulating layers 41 and a conductor layer 42 are laminated. That is, the wiring substrate of the embodiment includes the core substrate 100, the first and second build-up parts (10, 20) that are in contact with the core substrate 100 and form inner-layer parts of the wiring substrate, and the third and fourth build-up parts (30, 40) that form surface-layer parts on outer sides of the inner-layer parts. In the illustrated example, the fourth build-up part 40 has a structure in which one conductor layer 42 is provided on an outermost side of multiple laminated insulating layers 41. However, similar to the third build-up part 30, the fourth build-up part 40 may have a structure in which multiple insulating layers 41 and multiple conductor layers 42 are alternately laminated. The fourth build-up part 40 can include at least one insulating layer 41 and at least one conductor layer 42.

In the description of the wiring substrate of the present embodiment, a side farther from the core insulating layer 101 is referred to as “upper,” “upper side,” “outer side,” or “outer,” and a side closer to the core insulating layer 101 is referred to as “lower,” “lower side,” “inner side,” or “inner.” Further, for each of the structural components, a surface facing the opposite side with respect to the core substrate 100 is also referred to as an “upper surface,” and a surface facing the core substrate 100 side is also referred to as a “lower surface.” Therefore, in the description of each of the elements of the wiring substrate 1, a side farther from the core substrate 100 is also referred to as an “upper side,” “upper-layer side,” or “outer side,” or “upper” or “outer,” and a side closer to the core substrate 100 is also referred to as a “lower side,” “lower-layer side,” or “inner side,” or “lower” or “inner.”

The insulating layers 11 of the first build-up part 10 are also referred to as first insulating layers 11, and the conductor layers 12 of the first build-up part 10 are also referred to as first conductor layers 12. The insulating layers 21 of the second build-up part 20 are also referred to as second insulating layers 21, and the conductor layers 22 of the second build-up part 20 are also referred to as second conductor layers 22. The insulating layers 31 of the third build-up part 30 are also referred to as third insulating layers 31, and the conductor layers 32 of the third build-up part 30 are also referred to as third conductor layers 32. The insulating layer 41 of the fourth build-up part 40 is also referred to as a fourth insulating layer 41, and the conductor layer 42 of the fourth build-up part 40 is also referred to as a fourth conductor layer 42.

The third build-up part 30 includes a covering insulating layer 310 that covers the outermost third conductor layer 32 and the third insulating layer 31 exposed from conductor patterns of the third conductor layer 32. The fourth build-up part 40 includes a covering insulating layer 410 that covers the outermost fourth conductor layer 42 and the fourth insulating layer 41 exposed from conductor patterns of the fourth conductor layer 42. The covering insulating layers (310, 410) can be, for example, solder resist layers forming outermost insulating layers of the wiring substrate 1.

Openings (310a) are formed in the insulating layer 310, and conductor pads (32p) are exposed in the openings (310a). The openings (310a) are through holes penetrating the insulating layer 310 in a thickness direction, and the openings (310a) are filled with conductors. The conductors filling the openings (310a) form an outermost surface of the wiring substrate 1 and form connection elements (MP), which are, for example, metal posts that can be used to connect the wiring substrate 1 to an external electronic component. Openings (410a) are formed in the covering insulating layer 410, and conductor pads (42p) of the outermost fourth conductor layer 42 in the fourth build-up part 40 are exposed from the openings (410a).

Among the multiple third conductor layers 32 of the third build-up part 30, the outermost third conductor layer 32 is formed in a pattern having the multiple conductor pads (32p), and on the conductor pads (32p), the connection elements (MP) are formed, which are structural elements formed of outermost conductors of the third build-up part 30. The connection elements (MP) can be used for connection to connection pads of an external electronic component when the wiring substrate 1 is used. Upper surfaces of the connection elements (MP) can be electrically and mechanically connected to an external electronic component, for example, via a conductive bonding material such as solder (not illustrated) provided between the connection elements (MP) and connection pads of the external electronic component. That is, a surface (FA), which is formed of an outermost surface (exposed surfaces of the connection elements (MP) and the upper surface of the covering insulating layer 310) of the third build-up part 30 and is an outermost surface of the wiring substrate 1, can a component mounting surface on which an external electronic component can be mounted when the wiring substrate 1 is used.

In the illustrated example, the surface (FA) includes multiple component mounting regions (EA1, EA2) where electronic components can be respectively mounted. The illustrated component mounting regions (EA1, EA2) respectively correspond to regions where electronic components (E1, E2) are to be mounted. Examples of the electronic components (E1, E2) that can be mounted on the wiring substrate 1 include electronic components (for example, logic chips and memory elements) such as active components such as semiconductor integrated circuit devices and transistors. A surface (FB) on the opposite side with respect to the surface (FA) is formed of an exposed surface of the covering insulating layer 410 on the outermost side of the fourth build-up part 40 and upper surfaces of the conductor pads (42p) exposed from the openings (410a). The surface (FB) can be a connection surface to be connected to an external element such as an external wiring substrate (for example, a motherboard of any electrical device) when the wiring substrate 1 itself is mounted on the external element. The conductor pads (42p) can be connected to any substrate, electronic component, mechanism element, or the like.

Each of the insulating layers (101, 11, 21, 31, 41) of the wiring substrate 1 can be formed using an insulating resin such as an epoxy resin or a phenol resin. A fluorine resin, a liquid crystal polymer (LCP), a fluoroethylene resin (PTFE), a polyester resin (PE), or a modified polyimide resin (MPI) also may be used for the insulating layers (101, 11, 21, 31, 41). Each of the insulating layers (101, 11, 21, 31, 41) may also contain a reinforcing material (core material) such as a glass fiber. Each of the insulating layers (101, 11, 21, 31, 41) can contain an inorganic filler such as silica, or alumina. Each of the covering insulating layers (310, 410), which can be solder resist layers, can be formed using, for example, a photosensitive epoxy resin or polyimide resin, or the like.

When the insulating layers (11, 21, 31, 41) contain inorganic fillers, dimensions of the contained inorganic fillers may differ depending on the insulating layers (11, 21, 31, 41). Specifically, in particular, a maximum particle size of the inorganic filler that can be contained in the third insulating layers 31 of the third build-up part 30 may be smaller than a maximum particle size of the inorganic filler contained in the first and second insulating layers (11, 21) of the first and second build-up parts (10, 20). Further, values of relative permittivity and dielectric loss tangent of the third insulating layers 31 of the third build-up part 30 may differ from values of relative permittivity and dielectric loss tangent of the first and second insulating layers (11, 21) of the first build-up part 10 and second build-up part 20.

In the insulating layer 101 of the core substrate 100, through-hole conductors 103 are formed that penetrate the insulating layer 101 in the thickness direction and connect the conductor layer 102 forming the first surface (F1) of the core substrate 100 and the conductor layer 102 forming the second surface (F2) of the core substrate 100. Each of inner sides of the through-hole conductors 103 is filled with a resin body (103i) containing an epoxy resin or the like. In the first insulating layers 11, the second insulating layers 21, the third insulating layers 31, and the fourth insulating layers 41, via conductors (13, 23, 33, 43) connecting the conductor layers sandwiching the first-fourth insulating layers (11, 21, 31, 41) are respectively formed. In the illustrated example, the fourth build-up part 40 has a structure in which the via conductors 43 each penetrate the multiple insulating layers 41. However, similar to the third build-up part 30, the fourth build-up part 40 may have a structure in which multiple insulating layers 41 and multiple conductor layers 42 are alternately laminated, and the conductor layers sandwiching the insulating layers 41 are connected by via conductors 43.

The conductor layers (102, 12, 22, 32, 42), the via conductors (13, 23, 33, 43), the through-hole conductors 103, and the connection elements (MP) may be formed using any metal such as copper or nickel, and, for example, may each be formed of a metal foil such as a copper foil and/or a metal film formed by plating or sputtering or the like. The conductor layers (102, 12, 22, 32, 42), the via conductors (13, 23, 33, 43), the through-hole conductors 103, and the connection elements (MP) are each illustrated in FIG. 1 as having a single-layer structure but may each have a multilayer structure that includes two or more metal layers. For example, the conductor layers 102 that are respectively formed on the surfaces of the insulating layer 101 may each have a five-layer structure including a metal foil layer (preferably, a copper foil), an electroless plating film layer (preferably, an electroless copper plating film), and an electrolytic plating film layer (preferably, an electrolytic copper plating film). Further, the conductor layers (12, 22, 32, 42), the via conductors (13, 23, 33, 43), the through-hole conductors 103, and the connection elements (MP) may each have, for example, a two-layer structure including a metal film layer, which is an electroless plating film or a sputtering film, and an electrolytic plating film layer.

The conductor layers (102, 12, 22, 32, 42) of the wiring substrate 1 are each patterned to have predetermined conductor patterns. In the illustrated example, the first conductor layers 12 include first wirings (FW1), the second conductor layers 22 include second wirings (FW2), the third conductor layers 32 include third wirings (FW3), and the fourth conductor layer 42 includes fourth wirings (FW4). In the wiring substrate of the embodiment, in particular, the wirings (FW3) included in the third conductor layers 32 of the third build-up part 30 are formed as finer wirings than the wirings (FW2, FW3, FW4) included in the first, second, and fourth conductor layers (12, 22, 42).

Specifically, a minimum wiring width of the third wirings (FW3) included in the third conductor layers 32 is smaller than a minimum wiring width of the first, second, and fourth wirings (FW1, FW2, FW4) included in the first, second, and fourth conductor layers (12, 22, 42). Further, a minimum inter-wiring distance of the third wirings (FW3) included in the third conductor layers 32 is smaller than a minimum inter-wiring distance of the first, second, and fourth wirings (FW1, FW2, FW4) included in the first, second, and fourth conductor layers (12, 22, 42). In other words, the third build-up part 30 includes the finest third wirings (FW3) among the wirings that may be included in the conductor layers of the wiring substrate 1.

The conductor pads (32p) included in the outermost third conductor layer 32 of the third build-up part 30 can be electrically connected to an external electronic component that can be mounted on the wiring substrate 1 via the connection elements (MP). Among the illustrated multiple conductor pads (32p), the connection elements (MP) formed on the two conductor pads (32p) illustrated on the left are positioned in the component mounting region (EA1), and the connection elements (MP) formed on the two conductor pads (32p) illustrated on the right are positioned in the component mounting region (EA2). As illustrated, the connection elements (MP) positioned in these different component mounting regions (EA1, EA2) may be connected by the wirings included in the third build-up part 30. That is, the third conductor layers 32 may include so-called bridge wirings that electrically connect between the multiple connection elements (MP) that form different component mounting regions.

Further, in particular, a thickness of each of the third conductor layers 32 of the third build-up part 30 can differ from a thickness of each of the other conductor layers (102, 12, 22, 42) of the wiring substrate 1. Specifically, it may be possible that the thickness of each of the third conductor layers 32 is small compared to, in particular, the thickness of each of the first conductor layers 12 and the second conductor layers 22 among the conductor layers (102, 12, 22, 42) of the wiring substrate 1. For example, when a minimum conductor thickness of each of the first conductor layers 12 and the second conductor layers 22 is 10 μm or more, a maximum thickness of each of the third conductor layers 32 can be 7 μm or less.

From a point of view of suppressing warping of the wiring substrate 1, it is desirable that the number of the insulating layers 11 and the conductor layers 12 included in the first build-up part 10 and the number of the insulating layers 21 and the conductor layers 22 included in the second build-up part 20 are equal to each other. Further, from the same point of view, it is desirable that a difference in volume between the insulating layers (31, 310) of the third build-up part 30 and the insulating layers (41, 410) of the fourth build-up part 40 is within a predetermined range. Further, from the same point of view, it is desirable that a difference in volume between the conductors (the conductor layers 32, the via conductors 33, and the connection elements (MP)) of the third build-up part 30 and the conductors (the conductor layer 42 and the via conductors 43) of the fourth build-up part 40 is within a predetermined range.

Specifically, it is desirable that the volume of the insulating layers (31, 310) of the third build-up part 30 and the volume of the insulating layers (41, 410) of the fourth build-up part 40 are substantially equal to each other. Further, it is desirable that the volume occupied by the conductors (the volume occupied by the conductor layers 32, the via conductors 33, and the connection elements (MP)) in the third build-up part 30 and the volume occupied by the conductors (the volume occupied by the conductor layer 42 and the via conductors 43) in the fourth build-up part 40 are substantially equal to each other.

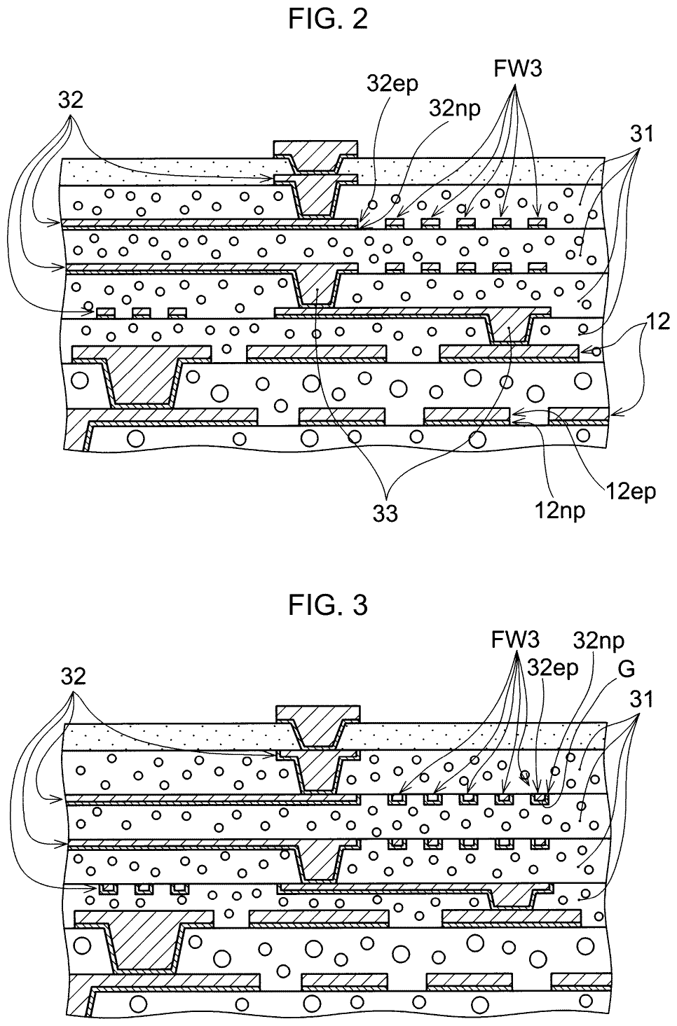

Next, with reference to FIG. 2, the structure of the third build-up part 30 forming a surface-layer part of the wiring substrate 1 is described in detail. FIG. 2 is an enlarged view of a region (II) surrounded by a one-dot chain line in FIG. 1.

As described above, the third conductor layers 32 included in the third build-up part 30 include the finest wirings (FW3) among the wirings included in the wiring substrate 1. Specifically, the wirings (FW3) included in the third conductor layers 32 are formed to have a minimum wiring width of 3 μm or less and a minimum inter-wiring distance of 3 μm or less. Further, the wirings (FW3) included in the third conductor layers 32 are formed to have an aspect ratio of 2.0 or more and 4.0 or less. In this way, since the third build-up part 30 has the wirings (FW3) that have relatively small wiring widths and inter-wiring distances and relatively high aspect ratios, it is possible to realize a wiring substrate that has highly reliable wirings provided at a relatively high density in a surface-layer part with reduced occurrence of a defect such as a disconnection. It is thought that more appropriate wirings corresponding to electrical signals carried in a surface-layer part of the wiring substrate can be provided. The via conductors 33 integrally formed with the conductor layers 32 included in the third build-up part 30 are formed to each have an aspect ratio ((depth from an upper surface of an insulating layer 31 to a bottom part of a via conductor 33)/(diameter at an upper side of the via conductor 33 (upper surface side of the insulating layer 31))) of about 0.5 or more and about 1.0 or less.

Further, as described above, the dimensions of the inorganic filler that can be contained in the third insulating layers 31 of the third build-up part 30 can differ from the dimensions of the inorganic fillers that can be contained in the other insulating layers of the wiring substrate 1. It may be possible that a maximum particle size of the inorganic filler that can be contained in the third insulating layers 31 is smaller than maximum particle sizes of the inorganic fillers that can be contained in the other insulating layers of the wiring substrate 1. In the case where an inorganic filler is contained in the third insulating layers 31 that are in contact with the wirings (FW3) formed at a relatively high density, when inorganic filler particles having relatively large particle sizes are positioned between adjacent wirings, a short circuit between the wirings may occur due to migration via surfaces of the filler particles. Therefore, since the maximum particle size of the filler that can be contained in the insulating layers 31 is relatively small, it may be possible that the risk of a short circuit in the wirings (FW3) is reduced. The term “particle size” in the description of filler particles means a linear distance between two most distant points on an outer surface of a filler particle. Specifically, for example, the maximum particle size of the inorganic filler that can be contained in the third insulating layers 31 can be 1 μm or less.

In the illustrated example, the first conductor layers 12 and the third conductor layers 32 each have a two-layer structure including a metal film layer and an electrolytic plating film layer. In the illustration, the first conductor layers 12 each include a metal film layer (12np) and an electrolytic plating film layer (12ep), and the third conductor layers 32 each include a metal film layer (32np) and an electrolytic plating film layer (32ep). The metal film layer (12np) included in the first conductor layers 12 can be an electroless copper plating film layer formed by electroless plating. The electrolytic plating film layer (12ep) can be an electrolytic copper plating film layer formed using the metal film layer (12np) as a power feeding layer. In particular, the metal film layer (32np) of the third conductor layers 32 can be a sputtering film layer formed by sputtering with a copper target. The metal film layer (32np), which is a sputtering film layer, has relatively good adhesion to the upper surfaces of the insulating layers 31, and can have a more uniform thickness. The electrolytic plating film layer (32ep) can be an electrolytic copper plating film layer formed using the metal film layer (32np) as a power feeding layer.

As will be described in detail later regarding a method for manufacturing a wiring substrate, the formation of each of the third conductor layers 32 included in the third build-up part 30 includes a process of polishing the upper surface of the each of the third conductor layers 32. Therefore, the upper surface of each of the third conductor layers 32 is flat with relatively low roughness, and thus, the conductor layers 32 (especially the wirings (FW3)) each have a relatively uniform thickness. Specifically, the upper surface of each of the third conductor layers has an arithmetic mean roughness (Ra) of 0.3 μm or less. Since the wirings (FW3) are formed to have relatively uniform thicknesses, an insertion loss of signals carried by the wirings (FW3) can be kept small. It is thought that good signal transmission by the wirings (FW3) can be realized.

The wirings (FW3) included in the third conductor layers 32 can be wirings for high frequency signal transmission. Therefore, it is preferable that the insulating layers 31 in contact with the wirings (FW3) have excellent high-frequency characteristics. From a point of view of realizing good signal transmission quality for the signals carried by the wirings (FW3), the third insulating layers 31 desirably have relatively low relative permittivity and dielectric loss tangent. When an insulating layer in contact with wirings has relatively high permittivity and dielectric loss tangent, a dielectric loss (transmission loss) of a high frequency signal transmitted via the wirings is relatively large. Therefore, the insulating layers 31 in contact with the wirings (FW3) are preferably formed of a material having relatively small permittivity and dielectric loss tangent, and preferably have, at a frequency of 5.8 GHz, a relative permittivity of 0.005 or less and a dielectric loss tangent of 4.0 or less.

FIG. 3 illustrates a cross-sectional view of a region corresponding to FIG. 2 in another example of the wiring substrate of the embodiment, in which the structure of each of the conductor layers 32 differs from the example illustrated in FIG. 2. In the example illustrated in FIG. 2, the third conductor layers 32 protrude upward from the upper surfaces of the insulating layers 31, whereas the third conductor layers 32 illustrated in FIG. 3 are embedded in the insulating layers 31 from the upper surfaces of the insulating layers 31. Specifically, in FIG. 3, the third conductor layers 32 are formed of conductors (the metal film layer (32np) and the electrolytic plating film layer (32ep)) filling grooves (G) formed in the lower-side insulating layers 31, and the wirings (FW3) included in the conductor layers 32 are formed as wirings (embedded wiring) embedded in the insulating layers 31.

The formation of the conductor layers 32 embedded downward from the upper surfaces of the insulating layers 31 as illustrated in FIG. 3 can include forming the grooves (G) in the insulating layers 31 by laser irradiation, and filling the grooves (G) with conductors (the metal film layer (32np), which can be a sputtering film layer, and the electrolytic plating film layer (32ep)). Further, the process of filling the grooves (G) with the conductors can include a process of removing, by polishing, the metal film layer (32np) and the electrolytic plating film layer (32ep) formed over a depth greater than that of the grooves (G). Therefore, similar to the conductor layers 32 described with reference to FIG. 2, for the third conductor layers 32 embedded in the insulating layers 31 illustrated in FIG. 3, the upper surfaces of the conductor layers 32 can also be polished surfaces.

In particular, as illustrated, when the wirings (FW3) are embedded wirings, since the inorganic filler particles contained in the insulating layers 31 have relatively small particle sizes (specifically, since the maximum particle size of the filler particles is relatively small), it may be possible that transmission quality of signals carried by the wirings (FW3) is improved. Specifically, in the formation of the wirings (FW3), when the grooves (G) are formed, the inorganic filler particles may be exposed in the grooves (G). In this case, since the particle sizes of the inorganic filler particles are relatively small, it may be possible that a change in cross-sectional area along a length direction of each of the wirings (FW3) to be formed is suppressed. Insertion loss of signals carried by the wirings (FW3) can be reduced.

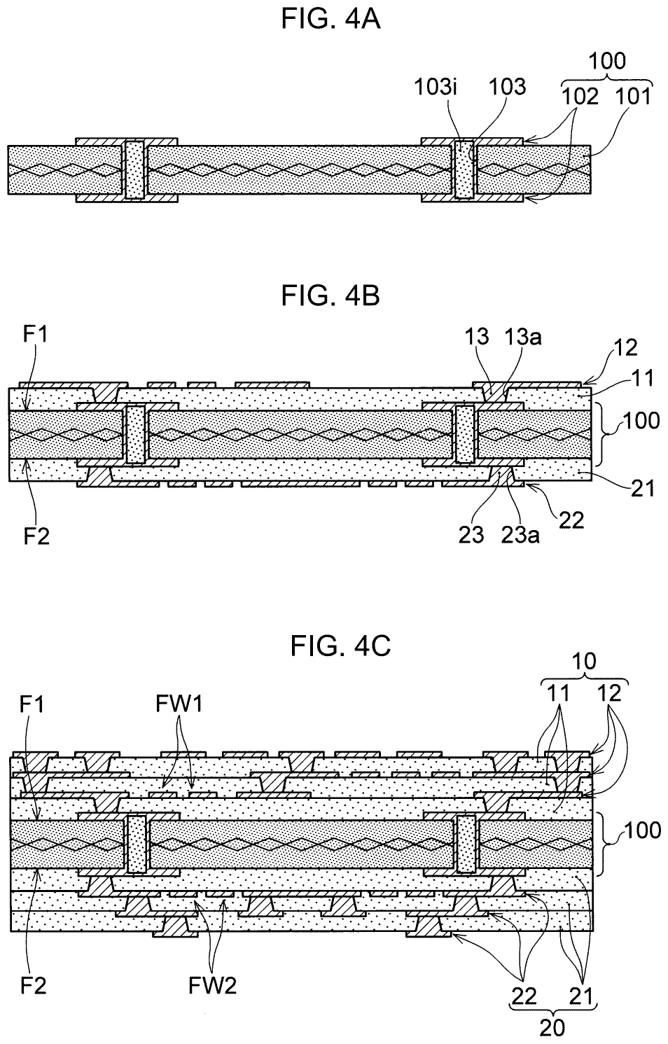

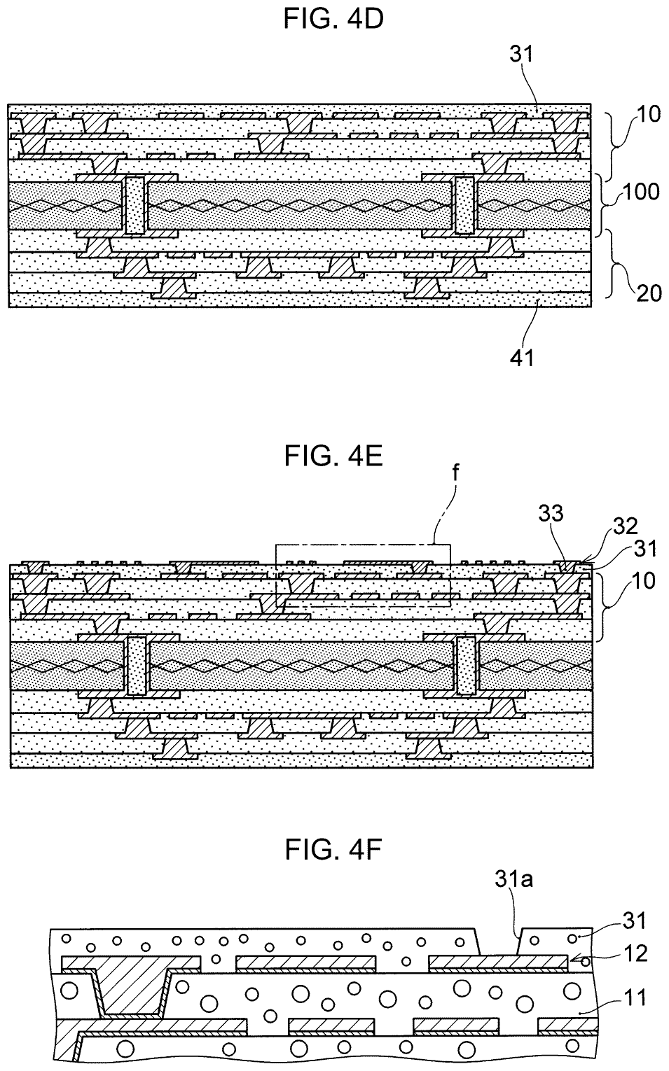

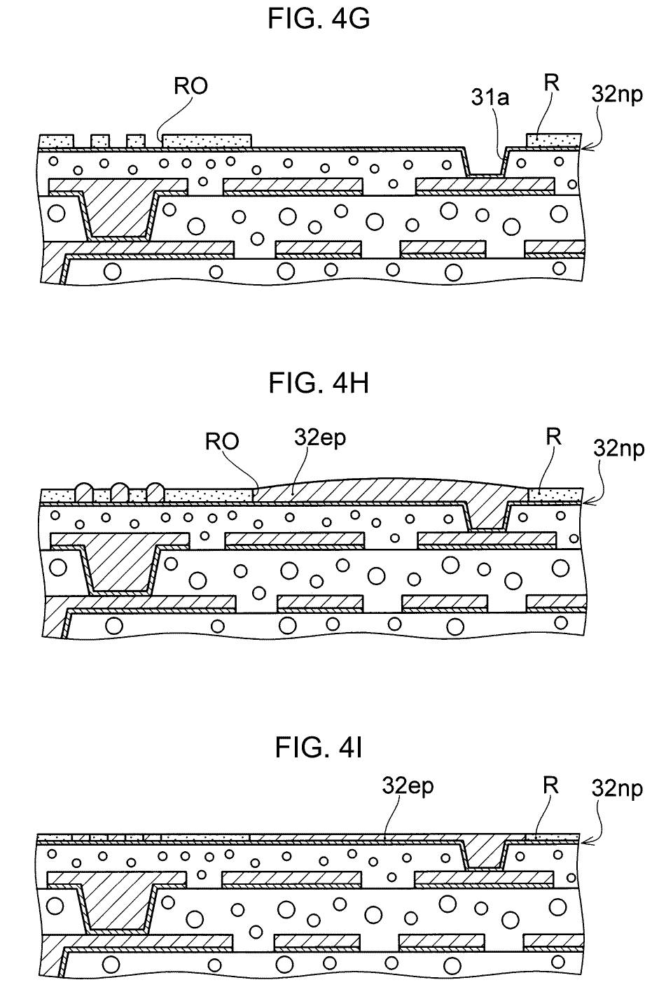

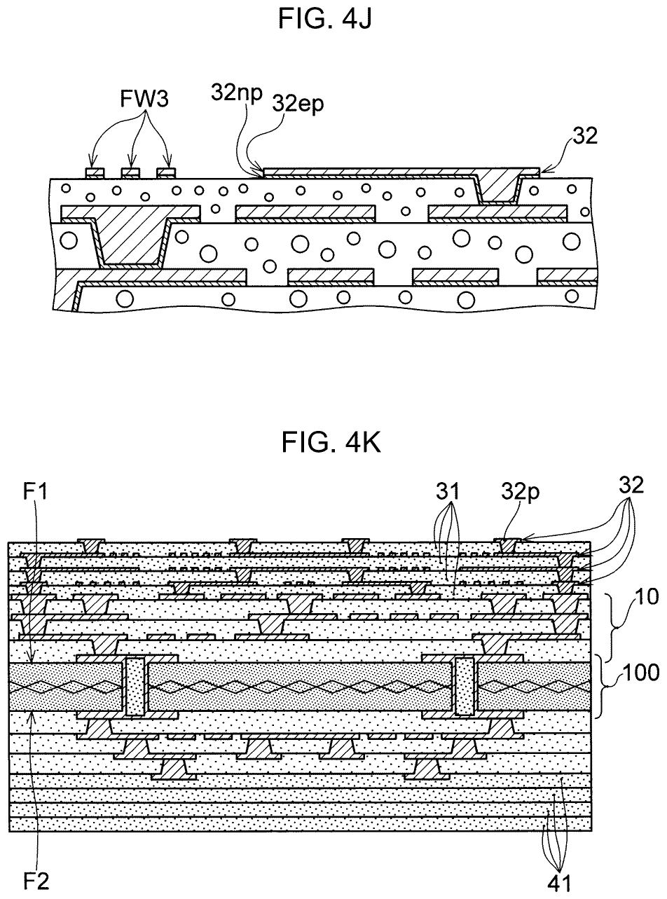

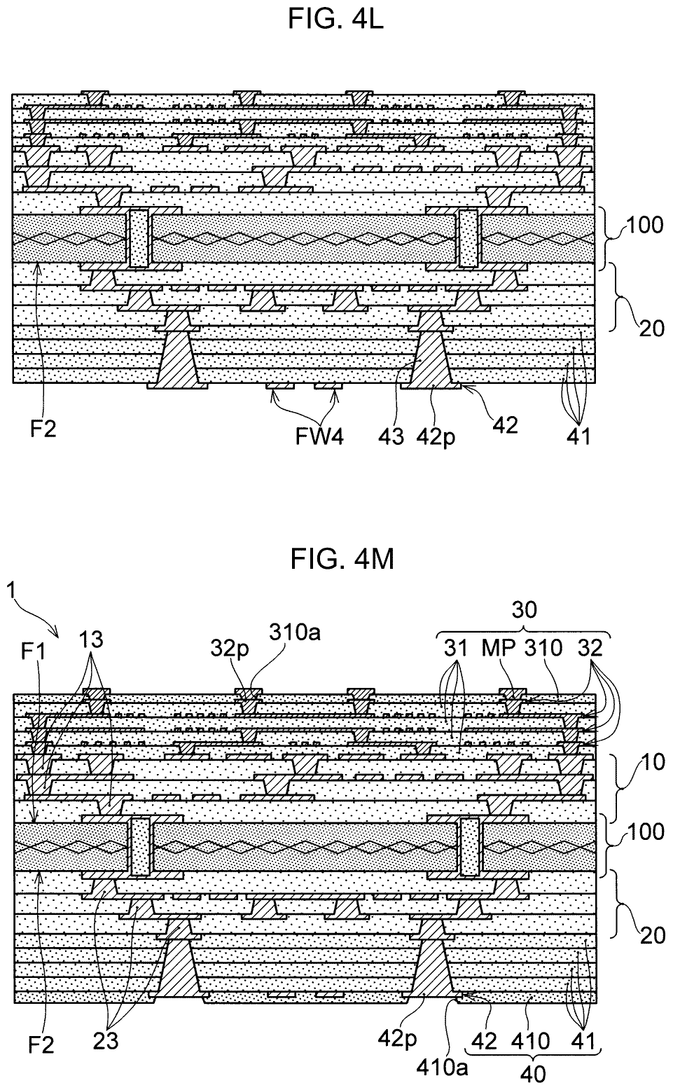

Next, with reference to FIGS. 4A-4M, a method for manufacturing a wiring substrate is described using a case where the wiring substrate 1 illustrated in FIG. 1 is manufactured as an example.

First, as illustrated in FIG. 4A, the core substrate 100 is prepared. In the preparation of the core substrate 100, for example, a double-sided copper-clad laminated plate including the core insulating layer 101 is prepared. Through holes are formed in the double-sided copper-clad laminate, for example, by drilling. For example, an electroless plating film layer is formed on inner walls of the through holes and on the upper surface of the metal foil, and an electrolytic plating film layer is formed on the electroless plating film layer using the electroless plating film layer as a power feeding layer. As a result, although illustrated as having a single-layer structure in the drawings, the through-hole conductors 103 are formed that have a two-layer structure including the electroless plating film layer and the electrolytic plating film layer and cover the inner walls of the through holes. The inner sides of the through-hole conductors 103 are filled with the resin bodies (103i) by injecting, for example, an epoxy resin into the inner sides of the through-hole conductors 103. After the filling resin bodies (103i) are solidified, on the resin bodies (103i) and the upper surface of the electrolytic plating film layer, an electroless plating film layer and an electrolytic plating film layer are further formed. As a result, although illustrated as each having a single-structure, the conductor layers 102 each having a five-layer structure including the metal foil layer, the electroless plating film layer, the electrolytic plating film layer, the electroless plating film layer, and the electrolytic plating film layer are respectively formed on both sides of the insulating layer 101. Then, the core substrate 100 having predetermined conductor patterns is obtained by patterning the conductor layers 102 using a subtractive method.

Next, as illustrated in FIG. 4B, an insulating layer 11 is formed on the first surface (F1) of the core substrate 100, and a conductor layer 12 is formed on the insulating layer 11. An insulating layer 21 is formed on the second surface (F2) of the core substrate 100, and a conductor layer 22 is laminated and formed on the insulating layer 21. For example, each of the insulating layers (11, 21) is formed by thermocompression bonding a film-like insulating resin onto the core substrate 100. The conductor layers (12, 22) are formed using any method for forming conductor patterns, such as a semi-additive method, at the same time as the via conductors (13, 23) filling openings (13a, 23a) that may be formed in the insulating layers (11, 21), for example, using laser.

Subsequently, as illustrated in FIG. 4C, on the first surface (F1) side of the core substrate 100, lamination of an insulating layer 11 and a conductor layer 12 is further repeated a necessary number of times, and the first build-up part 10 is formed. On the second surface (F2) side of the core substrate 100, lamination of an insulating layer and a conductor layer is further repeated a necessary number of times, and the second build-up part 20 is formed. The formation of the first and second build-up parts (10, 20) as inner-layer parts of the wiring substrate 1 is completed. In the illustrated example, the conductor layers (12, 22) of the build-up parts (10, 20) are formed to include the wirings (FW1, FW2) as conductor patterns.

Next, as illustrated in FIG. 4D, an insulating layer 31 is formed an outer side of the first build-up part 10, and an insulating layer 41 is formed on an outer side of the second build-up part 20. Each of the insulating layers (31, 41) can be formed by thermocompression bonding a resin film. In particular, the insulating layer 31 may be formed, for example, using an insulating resin containing a material different from that of the first and second insulating layers (11, 21). For example, the insulating layer 31 may be formed using a material containing an inorganic filler having a maximum particle size of 1 m or smaller than the maximum particle size of the inorganic filler contained in the insulating layers (11, 21). Further, for example, the insulating layer 31 may be formed using a material having a relative permittivity of 0.005 or less and a dielectric loss tangent of 4.0 or less at a frequency of 5.8 GHz. The insulating layer 31 and the insulating layer 41 can be formed using the same material and have substantially the same thickness.

Next, as illustrated in FIG. 4E, a conductor layer 32 is integrally formed with via conductors 33 on the insulating layer 31. In the following, the formation of the insulating layer 31 and the conductor layer 32 illustrated in FIGS. 4D and 4E is specifically described with reference to FIGS. 4F-4J, which correspond to enlarged views of a portion (f) corresponding to the region (II) of FIG. 1 illustrated in FIG. 2.

First, as illustrated in FIG. 4F, the insulating layer 31 can be formed on the surface of the conductor layer 12 and the surface of insulating layer 11 that is not covered by the conductor layer 12 by laminating a film-like resin containing an epoxy resin or the like and applying heat and pressure thereto. Next, through holes (31a) are formed in the insulating layer 31 at formation positions of the via conductors 33 (see FIG. 1). The formation of the through holes (31a) in the insulating layer 31 can be performed, for example, by irradiation with CO2 laser, excimer laser, or the like. After the formation of the through holes (31a), a desmear treatment, which removes processing-modified substances occurring at bottoms of the through holes (31a), may be performed. The desmear treatment to be performed may be, for example, a dry desmear treatment using a plasma gas. When the insulating layer 31 is formed using a photosensitive resin, the through holes (31a) may be formed by exposure and development using an exposure mask having openings corresponding to the through holes (31a). The through holes (31a) may be formed, for example, to have an aspect ratio ((depth from the upper surface of the insulating layer 31 to the bottom of a through hole (31a))/(diameter of the through hole (31a) at an upper side (upper surface side of the insulating layer 31))) of about 0.5 or more and about 1.0 or less.

Next, as illustrated in FIG. 4G, the metal film layer (32np) is formed on inner walls of through holes (31a) and over the entire surface of the insulating layer 31 by electroless plating or sputtering or the like. Preferably, the metal film layer (32np) is formed by sputtering. Subsequently, on the metal film layer (32np), a plating resist (R) having openings (RO) corresponding to desired conductor patterns to be included in the conductor layer 32 (see FIG. 1) is provided. The plating resist (R) having the openings (RO) may be provided, for example, by lamination of a dry film resist and by exposure and development using a mask having an opening pattern corresponding to the pattern of the openings (RO).

The openings (RO) provided in the resist (R) are formed in a pattern having relatively narrow opening widths and relatively small distances between adjacent openings, corresponding to the pattern of the wirings (FW3) (see FIG. 1) to be included in the conductor layer 32. The openings (RO) corresponding to the pattern of the wirings (FW3) have a minimum opening width of 3 μm or less. The openings (RO) corresponding to the pattern of the wirings (FW3) have a minimum inter-opening distance of 3 μm or less.

Next, as illustrated in FIG. 4H, the electrolytic plating film layer (32ep) is formed in the openings (RO) of the plating resist (R) by electrolytic plating using the metal film layer (32np) as a power feeding layer. The electrolytic plating film layer (32ep) is formed higher than the plating resist (R). That is, for example, as illustrated, the electrolytic plating film layer (32ep) may be formed such that an upper surface thereof has a convex spherical shape on an outer side the upper surface of the resist (R).

Next, as illustrated in FIG. 4I, upper-side portions of the electrolytic plating film layer (32ep) and the plating resist (R) are removed by polishing. The polishing can be performed until a desired thickness required for the electrolytic plating film layer (32ep) is achieved. The polishing may be performed, for example, by chemical mechanical polishing (CMP). By the polishing, the upper surface of the electrolytic plating film layer (32ep) can be formed to have an arithmetic mean roughness (Ra) of 0.3 μm or less.

Next, as illustrated in FIG. 4J, after the plating resist (R) is removed, an exposed portion of the metal film layer (32np) that is not covered by the electrolytic plating film layer (32ep) is removed by etching or the like. As a result, the conductor layer 32 is formed that has a two-layer structure including the metal film layer (32np) and the electrolytic plating film layer (32ep) and includes the wirings (FW3) having relatively high aspect ratios of 2.0 or more and 4.0 or less.

When a conductor layer 32 in a form of being embedded in an insulating layer 31 as illustrated in FIG. 3 is formed, instead of the processes illustrated in FIGS. 4F-4J, first, through holes for vias and grooves for the conductor layer are formed in the laminated insulating layer 31, for example, using CO2 laser or excimer laser. Subsequently, a metal film layer is formed by sputtering on inner surfaces of the through holes and the grooves and on the entire upper surface of the insulating layer 31, and an electrolytic plating film layer is further formed using the metal film layer as a power feeding layer. Subsequently, the metal film layer and the electrolytic plating film layer excluding portions inside the through holes and the grooves are removed by polishing, and the conductor layer 32 in a form of being embedded in the insulating layer 31 as illustrated in FIG. 3 is formed.

Next, as illustrated in FIG. 4K, on the first surface (F1) side of the core substrate 100, the formation of the insulating layer 31 and the conductor layer 32 is repeated a desired number of times, and on the second surface (F2) side of the core substrate 100, the lamination of the insulating layer 41 is repeated the same number of times. Processes up to the formation of the outermost conductor layer 32 on the first surface (F1) side of the core substrate 100 are completed. The outermost conductor layer 32 is formed in a pattern including the multiple conductor pads (32p).

Next, as illustrated in FIG. 4L, on the second surface (F2) side of the core substrate 100, the via conductors 43 penetrating the insulating layers 41 laminated on the second build-up part 20 are integrally formed with the conductor layer 42 on the upper side of the insulating layers 41. The conductor layer 42 is formed in a pattern including the conductor pads (42p) and the wirings (FW4).

Next, as illustrated in FIG. 4M, the covering insulating layer 310 is formed on the outermost conductor layer 32 on the first surface (F1) side of the core substrate 100 and on the insulating layer 31 exposed from the patterns of the conductor layer 32. In the insulating layer 310, the openings (310a) exposing the conductor pads (32p) are formed.

For example, the covering insulating layer 310 may be formed by forming a photosensitive epoxy resin film by spray coating, curtain coating, or film pasting, and the openings (310a) can be formed by exposure and development. On the second surface (F2) side of the core substrate 100, using the same method as the formation of the covering insulating layer 310, the covering insulating layer 410 having the openings (410a) exposing the conductor pads (42p) is formed on the conductor layer 42 and on the insulating layer 41 exposed from the patterns of the conductor layer 42. The formation of the fourth build-up part 40 is completed.

Subsequently, the openings (310a) are filled with conductors, and the connection elements (MP) are formed on the conductor pads (32p). Similar to the formation of the via conductors (13, 23) and the conductor layers (12, 22) described above, the connection elements (MP) may be formed, for example, using a semi-additive method. The formation of the third build-up part 30 on the first surface (F1) side of the core substrate 100 is completed, and the formation of the wiring substrate 1 is completed. In the process of forming the connection elements (MP), the surface of the covering insulating layer 410 and the upper surfaces of the conductor pads (42p) exposed from the openings (410a) can be appropriately protected by placing a protective plate of PET or the like.

The wiring substrate of the embodiment is not limited to those having the structures illustrated in the drawings and those having the structures, shapes, and materials exemplified herein. For example, each of the build-up parts of the wiring substrate may have any number of insulating layers and conductor layers. In the description of the embodiment, an example is illustrated in which the fourth build-up part 40 is formed of multiple insulating layers 41 and one conductor layer 42. However, similar to the build-up parts (10, 20, 30), the fourth build-up part 40 also may include multiple insulating layers 41 and multiple conductor layers 42.

Japanese Patent Application Laid-Open Publication No. 2019-75398 describes a printed wiring board including a core substrates, a first low-density build-up layer formed on a first surface of the core substrate, a second low-density build-up layer formed on a second surface of the core substrate, a first high-density build-up layer formed on the first low-density build-up layer on the opposite side with respect to the core substrate, and a second high-density build-up layer formed on the second low-density build-up layer on the opposite side with respect to the core substrate.

In the printed wiring board described in Japanese Patent Application Laid-Open Publication No. 2019-75398, the conductor layers of the first and second high-density build-up layers with similar conductor densities are formed thinner than the conductor layers of the first and second low-density buildup layers. It is thought that aspect ratios of wirings included in the conductor layers of the first and second high-density build-up layers may be relatively low. Further, it is thought that signals carried by the wirings included in the first and second high-density build-up layers may have a high insertion loss.

A wiring substrate according to an embodiment of the present invention includes: a core substrate that has a first surface and a second surface on the opposite side with respect to the first surface; a first build-up part that is formed on the first surface and includes multiple first insulating layers and multiple first conductor layers, which are alternately laminated; a second build-up part that is formed on the second surface and includes multiple second insulating layers and multiple second conductor layers, which are alternately laminated; a third build-up part that is formed on the first build-up part and includes multiple third insulating layers and multiple third conductor layers, which are alternately laminated; and a fourth build-up part that is formed on the second build-up part and includes at least one fourth insulating layer and at least one fourth conductor layer, which are alternately laminated. Outermost surfaces of the wiring substrate are respectively formed of an outermost surface of the third build-up part and an outermost surface of the fourth build-up part. A minimum wiring width of wirings included in the third conductor layers is smaller than a minimum wiring width of wirings included in the first conductor layers, the second conductor layers, and the fourth conductor layer. A minimum inter-wiring distance of the wirings included in the third conductor layers is smaller than a minimum inter-wiring distance of the wirings included in the first conductor layers, the second conductor layers, and the fourth conductor layer. The wirings included in the third conductor layers have a minimum wiring width of 3 μm or less and a minimum inter-wiring distance of 3 μm or less. The wirings included in the third conductor layers have an aspect ratio of 2.0 or more and 4.0 or less. Upper surfaces of the wirings included in the third conductor layers are polished surfaces.

According to an embodiment of the present invention, it is thought that a wiring substrate is provided that includes wirings that are relatively fine, have a high aspect ratio, have relatively good thickness uniformity, and have a relatively low insertion loss for carried signals.

Obviously, numerous modifications and variations of the present invention are possible in light of the above teachings. It is therefore to be understood that within the scope of the appended claims, the invention may be practiced otherwise than as specifically described herein.

1. A wiring substrate, comprising:
a core substrate;
a first build-up part formed on a first surface of the core substrate and comprising a plurality of first insulating layers and a plurality of first conductor layers;
a second build-up part formed on a second surface of the core substrate on an opposite side with respect to the first surface and comprising a plurality of second insulating layers and a plurality of second conductor layers;
a third build-up part formed on the first build-up part and comprising a plurality of third insulating layers and a plurality of third conductor layers such that the third build-up part has an outermost surface forming an outermost surface of the wiring substrate; and
a fourth build-up part formed on the second build-up part and comprising at least one fourth insulating layer and at least one fourth conductor layer such that the fourth build-up part has an outermost surface forming an outermost surface of the wiring substrate,
wherein the third build-up part is formed such that a minimum wiring width of wirings in the third conductor layers is smaller than a minimum wiring width of wirings in the first conductor layers, the second conductor layers, and the fourth conductor layer, a minimum inter-wiring distance of the wirings in the third conductor layers is smaller than a minimum inter-wiring distance of the wirings in the first conductor layers, the second conductor layers, and the fourth conductor layer, and the wirings in the third conductor layers have the minimum wiring width of 3 μm or less, the minimum inter-wiring distance of 3 μm or less, and an aspect ratio in a range of 2.0 to 4.0.

2. The wiring substrate according to claim 1, wherein each of the first insulating layers, the second insulating layers, and the third insulating layers includes an inorganic filler, and the third build-up part is formed such that a maximum particle size of the inorganic filler in the third insulating layers is smaller than a maximum particle size of the inorganic fillers in the first insulating layers and the second insulating layers.

3. The wiring substrate according to claim 1, wherein each of the third conductor layers has a thickness of 7 μm or less, and each of the first conductor layers and the second conductor layers has a thickness of 10 μm or more.

4. The wiring substrate according to claim 1, wherein the third build-up part is formed such that the wirings in the third conductor layers are formed in grooves formed in the third insulating layers.

5. The wiring substrate according to claim 1, wherein the wirings in each of the first conductor layers, the second conductor layers, and the third conductor layers include a metal film layer and an electrolytic plating film layer such that the metal film layer of the wirings in the first conductor layers and the second conductor layers is an electroless plated film layer and that the metal film layer of the wirings in the third conductor layers is a sputtering film layer.

6. The wiring substrate according to claim 1, wherein the third build-up part includes a plurality of via conductors penetrating through the third insulating layers such that the via conductors have an aspect ratio in a range of 0.5 to 1.0.

7. The wiring substrate according to claim 1, wherein the third build-up part is formed such that the wirings in the third conductor layers have upper surfaces having a surface roughness of 0.3 μm or less in arithmetic mean roughness.

8. The wiring substrate according to claim 1, wherein the third build-up part is formed such that the third insulating layers have a dielectric loss tangent of 0.005 or less and a relative permittivity of 4.0 or less at a frequency of 5.8 GHz.

9. The wiring substrate according to claim 1, wherein the third build-up part is formed such that a volume of the insulating layers in the third build-up part is substantially equal to a volume of the insulating layers in the fourth build-up part.

10. The wiring substrate according to claim 1, wherein the third build-up part is formed such that a volume of conductors in the third build-up part is substantially equal to a volume of conductors in the fourth build-up part.

11. The wiring substrate according to claim 1, wherein the third build-up part is formed such that the wirings in the third conductor layers have polished upper surfaces.

12. The wiring substrate according to claim 11, wherein each of the first insulating layers, the second insulating layers, and the third insulating layers includes an inorganic filler, and the third build-up part is formed such that a maximum particle size of the inorganic filler in the third insulating layers is smaller than a maximum particle size of the inorganic fillers in the first insulating layers and the second insulating layers.

13. The wiring substrate according to claim 11, wherein each of the third conductor layers has a thickness of 7 μm or less, and each of the first conductor layers and the second conductor layers has a thickness of 10 μm or more.

14. The wiring substrate according to claim 11, wherein the third build-up part is formed such that the wirings in the third conductor layers are formed in grooves formed in the third insulating layers.

15. The wiring substrate according to claim 11, wherein the wirings in each of the first conductor layers, the second conductor layers, and the third conductor layers include a metal film layer and an electrolytic plating film layer such that the metal film layer of the wirings in the first conductor layers and the second conductor layers is an electroless plated film layer and that the metal film layer of the wirings in the third conductor layers is a sputtering film layer.

16. The wiring substrate according to claim 11, wherein the third build-up part includes a plurality of via conductors penetrating through the third insulating layers such that the via conductors have an aspect ratio in a range of 0.5 to 1.0.

17. The wiring substrate according to claim 11, wherein the third build-up part is formed such that the wirings in the third conductor layers have upper surfaces having a surface roughness of 0.3 μm or less in arithmetic mean roughness.

18. The wiring substrate according to claim 11, wherein the third build-up part is formed such that the third insulating layers have a dielectric loss tangent of 0.005 or less and a relative permittivity of 4.0 or less at a frequency of 5.8 GHz.

19. The wiring substrate according to claim 11, wherein the third build-up part is formed such that a volume of the insulating layers in the third build-up part is substantially equal to a volume of the insulating layers in the fourth build-up part.

20. The wiring substrate according to claim 11, wherein the third build-up part is formed such that a volume of conductors in the third build-up part is substantially equal to a volume of conductors in the fourth build-up part.
